(19) United States
(12) Patent Application Publication
(10) Pub. No.: US 2019/0155142 A1
(43) Pub. Date: May 23, 2019

(54) PHASE SHIFT MASK AND FABRICATION METHOD THEREOF

(71) Applicant: Powerchip Technology Corporation, Hsinchu (TW)

(72) Inventor: Yi-Kai Lai, Taoyuan City (TW)

(21) Appl. No.: 15/928,059

(22) Filed: Mar. 21, 2018

(30) Foreign Application Priority Data
Nov. 23, 2017 (TW) 106140736

(51) Int. Cl. G03F 1/26

(52) U.S. Cl. CPC G03F 1/26

(57) ABSTRACT

A phase shift mask for transferring a layout in a photolithography process includes a substrate and a patterned phase shift layer. The patterned phase shift layer is disposed on the substrate and includes at least one device pattern aperture and a plurality of dummy pattern apertures, the device pattern aperture and the dummy pattern apertures expose the surface of the substrate, and the dummy pattern apertures are disposed around the device pattern aperture. The patterned phase shift layer has a predetermined thickness such that the phase difference between the light passing through the patterned phase shift layer and the light passing through the device pattern aperture or the dummy pattern apertures during the photolithography process is 180 degrees. The transmittance ratio of the patterned phase shift layer is 100%.

### CROSS REFERENCE TO RELATED APPLICATION

The present application claims the priority benefit of Taiwan application serial no. 106140736, filed Nov. 23, 2017. The entirety of the above-mentioned patent application is hereby incorporated by reference herein and made a part of this specification.

### BACKGROUND OF THE INVENTION

### 1. Field of the Invention

The present invention relates to a mask and a fabrication method thereof, more particularly, to a phase shift mask and a fabrication method thereof.

### 2. Description of the Prior Art

Generally, fabricating a semiconductor device requires complex semiconductor fabrication processes, wherein various circuit layouts on the chip need to be defined by multiple photolithography processes. In the photolithography process, the resolution of exposure is an important factor affecting the photolithography quality, and the phase shift mask (PSM) is therefore developed for enhancing the resolution of the photolithography process. However, in conventional methods for fabricating PSM, the phase shift layer is mainly formed with molybdenum-silicon (MoSi) material and the fabrication requires plural etching processes. It is difficult to prevent the phase shift layer or the surface of substrate from being damaged by the plural etching processes during the fabrication, and thus the uniformity of critical dimensions (CD) of patterns on the mask may decrease. In addition, since the light transmittance of MoSi material is about 6%, the resolution of the conventional PSM is low and the side lobe effect occurs in the photolithography process as well. For example, defect patterns that are not included in the original circuit layout are formed in proximity of circuit patterns (e.g., contact holes) in the photolithography process. Accordingly, the resolution enhancement and side lobe effect reduction of the photolithography process are still important problems required to be solved in the industry.

### SUMMARY OF THE INVENTION

The present invention provides a phase shift mask and a fabrication method thereof to enhance the resolution of photolithography process and reduce the side lobe effect.

According to an embodiment of the present invention, a phase shift mask configured to transfer a layout through a photolithography process is provided. The phase shift mask includes a substrate and a patterned phase shift layer. The patterned phase shift layer is disposed on the substrate, wherein the patterned phase shift layer includes at least one device pattern aperture and a plurality of dummy pattern apertures. The at least one device pattern aperture and the dummy pattern apertures expose a portion of a surface of the substrate, and the dummy pattern apertures are disposed adjacent to the at least one device pattern aperture and surround the at least one device pattern aperture. The patterned phase shift layer includes a predetermined thickness which makes a phase difference between an exposure light beam passing through the patterned phase shift layer and an exposure light beam passing through the at least one device pattern aperture or the dummy pattern apertures in the photolithography process be 180 degrees, and a light transmittance of the patterned phase shift layer is 100%. The at least one device pattern aperture corresponds to at least one device pattern of the layout, and the at least one device pattern is transferred to a target substrate through the photolithography process.

According to an embodiment of the present invention, a fabrication method of a phase shift mask is provided. The phase shift mask is applied to transferring a layout through a photolithography process, and the layout comprises at least one device pattern. The fabrication method of the phase shift mask includes following steps. First, a phase shift layer with a predetermined thickness is formed on a substrate, and at least one predetermined device region, a plurality of dummy pattern regions, and a background region are defined on the substrate, wherein the at least one predetermined device region corresponds to the at least one device pattern of the layout. Next, a partial irradiation process is performed to the phase shift layer by using an energy beam to illuminate the phase shift layer, wherein the energy beam illuminates the background region but does not illuminate the at least one predetermined device region and the dummy pattern regions. Next, the phase shift layer is patterned, wherein a portion of the phase shift layer in the at least one predetermined device region and the dummy pattern regions not being illuminated is removed, a portion of the phase shift layer in the background region being illuminated is retained, so as to form at least one device pattern aperture and a plurality of dummy pattern apertures in the phase shift layer, wherein the at least one device pattern aperture and the dummy pattern apertures expose a portion of a surface of the substrate.

This invention provides the phase shift layer having the predetermined thickness for forming the patterned phase shift layer in the phase shift mask. In this invention, the resolution of exposure process can be enhanced and the side lobe effect can be reduced by using the phase shift layer that includes the material with 100% light transmittance and disposing the dummy pattern apertures in the phase shift mask. In addition, the etching process is not required in the method of fabricating the phase shift mask in this invention, so that defects formed in the conventional phase shift mask by the etching process can be avoided.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram illustrating a layout being transferred by a phase shift mask according to an embodiment of this invention.

FIGS. 2-7 are schematic diagrams illustrating a fabrication method of the phase shift mask of the embodiment of this invention.

FIG. 8 is a schematic diagram illustrating a process flow of the fabrication method of the phase shift mask of this invention.

FIG. 9 is a schematic diagram illustrating applying the phase shift mask to a photolithography process of the embodiment of this invention.

FIG. 10 is a schematic diagram illustrating an exposure result of the phase shift mask of the embodiment of this invention.

### DETAILED DESCRIPTION

To provide a better understanding of this invention, preferred embodiments will be detailed as follows. The preferred embodiments of this invention are illustrated in the accompanying drawings with numbered elements to elaborate a phase shift mask and a fabrication method thereof and effects to be achieved in this invention. It is noted that, for purposes of illustrative clarity and being easily understood by the readers, various features illustrated in various drawings may not be drawn to scale, and the dimension or scale of each device shown in drawings are only illustrative and are not intended to limit the scope of this invention.

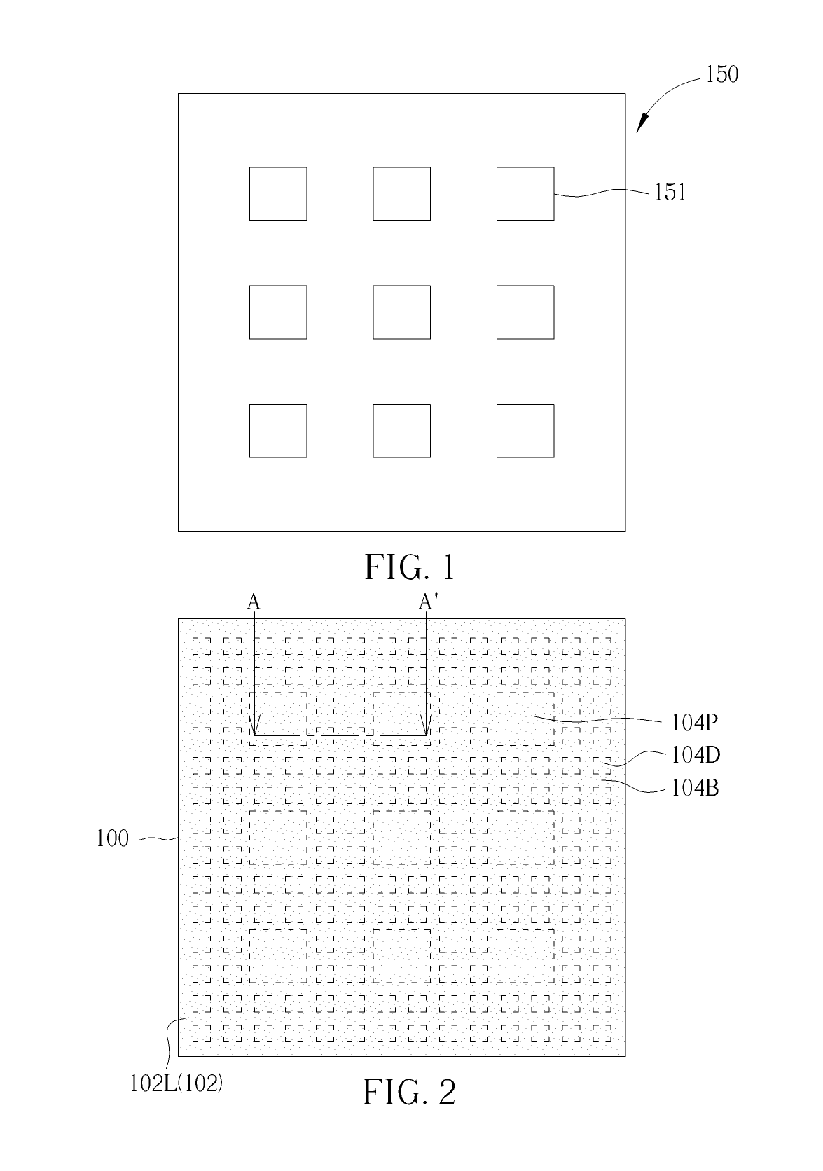

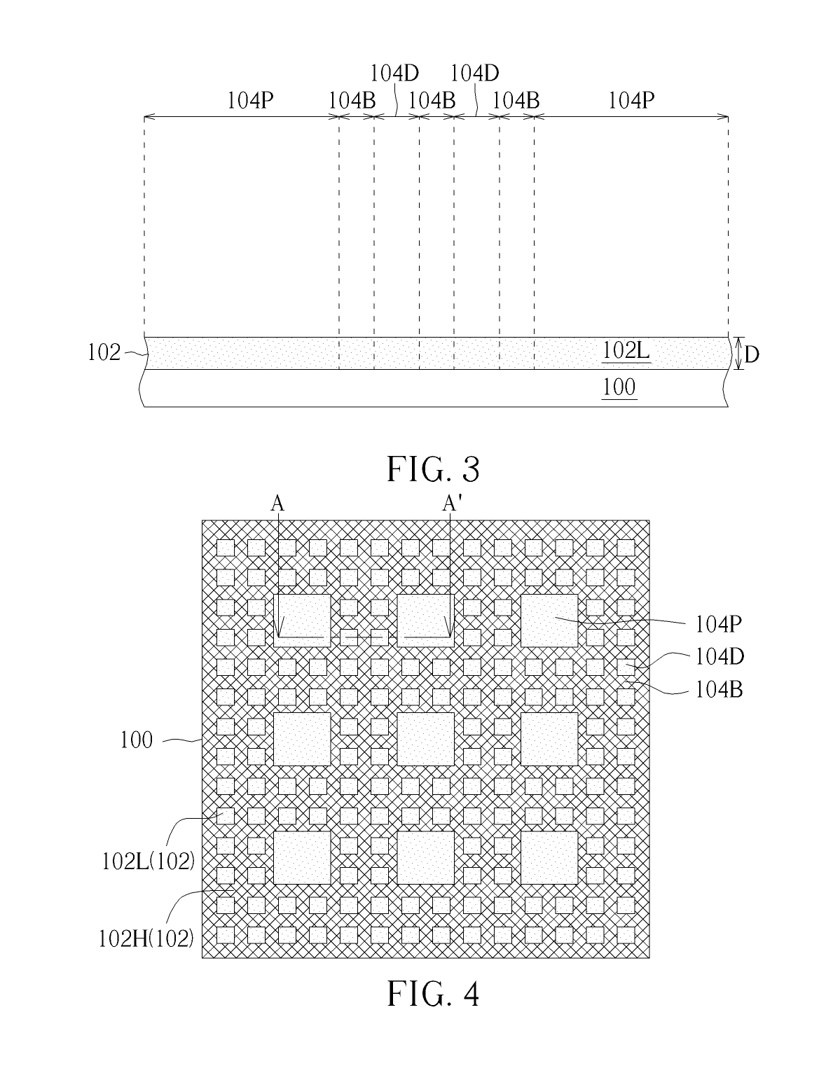

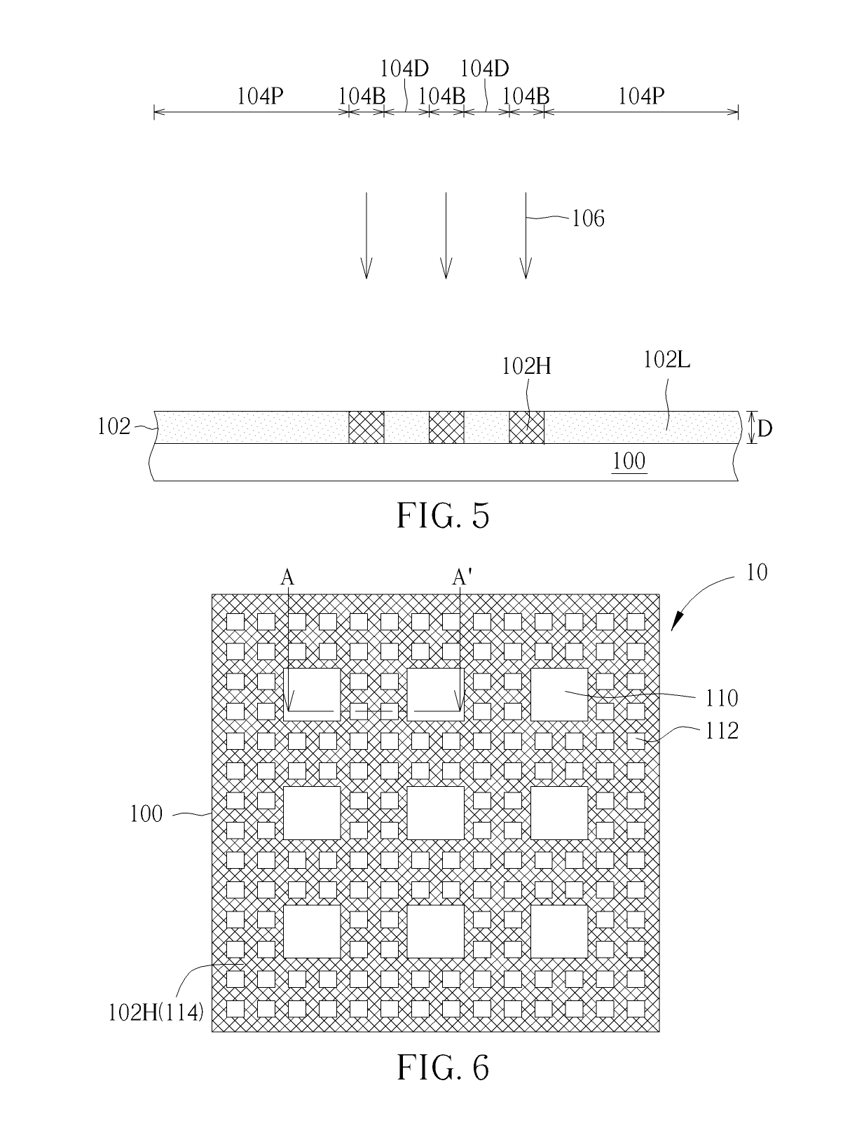

Referring to FIG. 1 to FIG. 8, FIG. 1 is a schematic diagram illustrating a layout being transferred by a phase shift mask according to an embodiment of this invention, FIGS. 2-7 are schematic diagrams illustrating a fabrication method of the phase shift mask of the embodiment of this invention, and FIG. 8 is a schematic diagram illustrating a process flow of the fabrication method of the phase shift mask of this invention. FIG. 2, FIG. 4, and FIG. 6 are schematic diagrams illustrating top views of different fabrication stages, and FIG. 3, FIG. 5, and FIG. 7 are schematic diagrams respectively illustrating cross-sectional views taken along a cross-line A-A′ in FIG. 2, FIG. 4, and FIG. 6. Please refer to FIG. 1, a phase shift mask of this embodiment is used for transferring patterns in a layout 150 (e.g., circuit layout) to a substrate. The device patterns 151 in the layout 150 are patterns of contact holes for example, and the device patterns 151 of this embodiment are disposed uniformly in a matrix arrangement in the layout 150, but not limited thereto. The device patterns 151 included in the layout 150 may include patterns of other devices having different shapes or arrangements. As shown in FIG. 2, FIG. 3, and FIG. 8, a step S10 according to the fabrication method of the phase shift mask of this invention is performed first, wherein a substrate 100 is provided, and a phase shift layer 102 with lower crosslinking degree is formed on the substrate 100. The substrate 100 may be a transparent substrate and may be formed of transparent materials such as quartz, but not limited thereto. The phase shift layer 102 may be formed on a surface of the substrate 100 entirely for example, and the method of forming the phase shift layer 102 may include spin coating method, but not limited thereto. The phase shift layer 102 includes a predetermined thickness D, and the material of the phase shift layer 102 includes a low crosslinking degree material. For example, the material of the phase shift layer 102 in this embodiment is hybrid organic siloxane polymer (HOSP) having cage-like structure. The crosslinking degree of the HOSP material having cage-like structure is relatively low, and therefore the HOSP material having cage-like structure is referred to as “low crosslinking degree material 102L” hereinafter. However, the material of the phase shift layer 102 is not limited to HOSP. In other embodiments, the material of the phase shift layer 102 may include methylsilsesquioxane (MSQ), hydrogen silsesquioxane (HSQ), or other crosslinking materials. In addition, at least one predetermined device region 104P, a plurality of dummy pattern regions 104D, and a background region 104B can be defined on the substrate 100. In this embodiment, a plurality of predetermined device regions 104P are included on the substrate 100, wherein the location and the shape of each predetermined device region 104P correspond to one of the device patterns 151 in the layout 150 shown in FIG. 1. The dummy pattern regions 104D can be disposed uniformly in a matrix arrangement around the predetermined device regions 104P or between the adjoining predetermined device regions 104P. Each dummy pattern region 104D in this embodiment is a square region having four equal side lengths, but not limited thereto. The portion except the predetermined device regions 104P and the dummy pattern regions 104D on the substrate 100 is defined as the background region 104B, and the background region 104B is also the portion of the phase shift mask that does not include pattern openings when the fabrication of the phase shift mask is finished. It is noteworthy that the dummy pattern regions 104D are not included in the layout 150, and the dummy pattern regions 104D are additionally disposed according to the fabrication method of the phase shift mask of this invention.

As shown in FIG. 4 and FIG. 5, a step S12 is performed next. A partial irradiation process is performed to the phase shift layer 102. The phase shift layer 102 is illuminated by an energy beam 106, wherein the energy beam 106 illuminates the background region 104B but does not illuminate the predetermined device regions 104P and the dummy pattern regions 104D, so that the low crosslinking degree material 102L in the background region 104B changes structurally due to the illumination of the energy beam 106. In this embodiment, the structure of the HOSP material that originally has cage-like structure is changed and transformed into a network structure due to the illumination of the energy beam 106, which means the HOSP material has a network structure after being illuminated. The crosslinking degree of the HOSP material having network structure is relatively high and is referred to as “high crosslinking degree material 102H” hereinafter. In short, a portion of the phase shift layer 102 in the background region 104B is formed of the high crosslinking degree material 102H having network structure after the partial irradiation process, and another portion of the phase shift layer 102 in the predetermined device regions 104P and the dummy pattern regions 104D is still formed of the low crosslinking degree material 102L having cage-like structure. In this embodiment, light transmittances of the low crosslinking degree material 102L and the high crosslinking degree material 102H are both 100%. Additionally, the energy beam 106 used in this embodiment may be an electron beam for example, and the partial irradiation process may be an electron beam irradiation process for example, but not limited thereto.

Next, as shown in FIG. 6 and FIG. 7, a step S14 is performed, wherein a patterning process 108 is performed to the phase shift layer 102 to remove the portion of the phase shift layer 102 in the predetermined device regions 104P and the dummy pattern regions 104D which is not illuminated by the energy beam 106, and the portion of the phase shift layer 102 in the background region 104B which is illuminated by the energy beam 106 is retained. That is to say, the low crosslinking degree material 102L in the predetermined device regions 104P and the dummy pattern regions 104D is removed, and the high crosslinking degree material 102H in the background region 104B is retained, so as to form a plurality of device pattern apertures 110 and a plurality of dummy pattern apertures 112 in the phase shift layer 102. The device pattern apertures 110 and the dummy pattern apertures 112 expose a portion of the surface of the substrate 100. Accordingly, a patterned phase shift layer 114 including the predetermined thickness D is formed. The device pattern apertures 110 and the dummy pattern apertures 112 are formed corresponding to the patterns of the abovementioned predetermined device regions 104P and dummy pattern regions 104D. The device pattern apertures 110 also correspond to the device patterns 151 of the layout 150, and the device pattern apertures 110 can be transferred to a target substrate during a photolithography process. As mentioned above, the layout 150 does not include patterns corresponding to the dummy pattern apertures 112. The dummy pattern apertures 112 are additionally disposed in the phase shift mask according to the design of this invention, so as to improve the quality of the exposure process. Therefore, the dummy pattern apertures 112 will not be transferred to the target substrate in the exposure process. According to this embodiment, the dummy pattern apertures 112 are disposed in a matrix arrangement in the patterned phase shift layer 114, and the dummy pattern apertures 112 are disposed adjacent to each device pattern aperture 110 and surround each device pattern aperture 110. Distances between each device pattern aperture 110 and the dummy pattern apertures 112 are greater than 0 micrometer, such that each device pattern aperture 110 and the dummy pattern apertures 112 separate from each other with certain distances. In addition, a distance d1 between any two adjacent dummy pattern apertures 112 is less than or equal to a size w1 of the dummy pattern apertures 112. The size w1 may be the length, width, or diameter of at least one of or all of the dummy pattern apertures 112 for instance. For example, the size w1 of the dummy pattern apertures 112 is less than or equal to a resolution limit of a lithographic apparatus (e.g., exposure apparatus). Patterns of the device pattern apertures 110 and the dummy pattern apertures 112 are squares in this embodiment for example, but not limited thereto. In other embodiments, patterns of the device pattern apertures 110 and the dummy pattern apertures 112 may respectively have different shapes according to different requirements. For example, one of the device pattern apertures 110 and the dummy pattern apertures 112 may have round shape, or both of the device pattern apertures 110 and the dummy pattern apertures 112 may have round shapes.

In this embodiment, the patterning process 108 can be a developing process, and a solvent can be used to remove the low crosslinking degree material 102L and retain the high crosslinking degree material 102H. For example, the solvent used in the developing process can be propyl acetate when the material of the phase shift layer 102 is HOSP. In other embodiments, alcohol may be selected as the solvent when the material of the phase shift layer 102 is MSQ, and tetramethylammonium hydroxide (TMAH) may be selected as the solvent when the material of the phase shift layer 102 is HSQ. According to the description above, a phase shift mask 10 can be fabricated by the method of this embodiment, wherein the fabrication is simple.

Therefore, the phase shift mask 10 of this invention can be fabricated according to the method mentioned above, wherein the phase shift mask 10 includes a substrate 100 and a patterned phase shift layer 114. The patterned phase shift layer 114 is disposed on the substrate 100 and includes at least one device pattern aperture 110 and a plurality of dummy pattern apertures 112, wherein the at least one device pattern aperture 110 and the dummy pattern apertures 112 expose a portion of a surface of the substrate 100. Additionally, the patterned phase shift layer 114 of this embodiment includes a plurality of device pattern apertures 110, wherein the dummy pattern apertures 112 are disposed adjacent to each device pattern aperture 110 and surround each device pattern aperture 110. The size of the dummy pattern apertures 112 is less than or equal to the resolution limit of the lithographic apparatus. The material of the patterned phase shift layer 114 includes the high crosslinking degree material 102H, and the high crosslinking degree material 102H includes HOSP, MSQ, or HSQ, but not limited thereto.

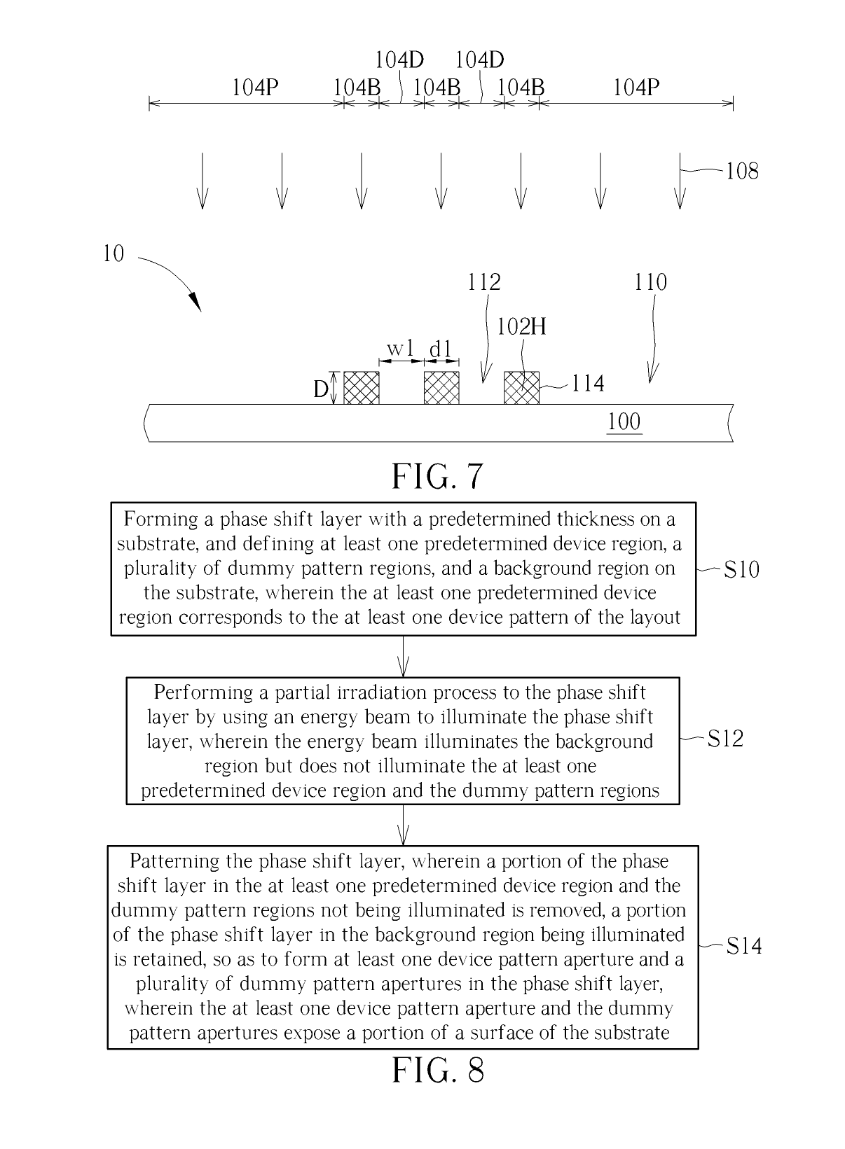

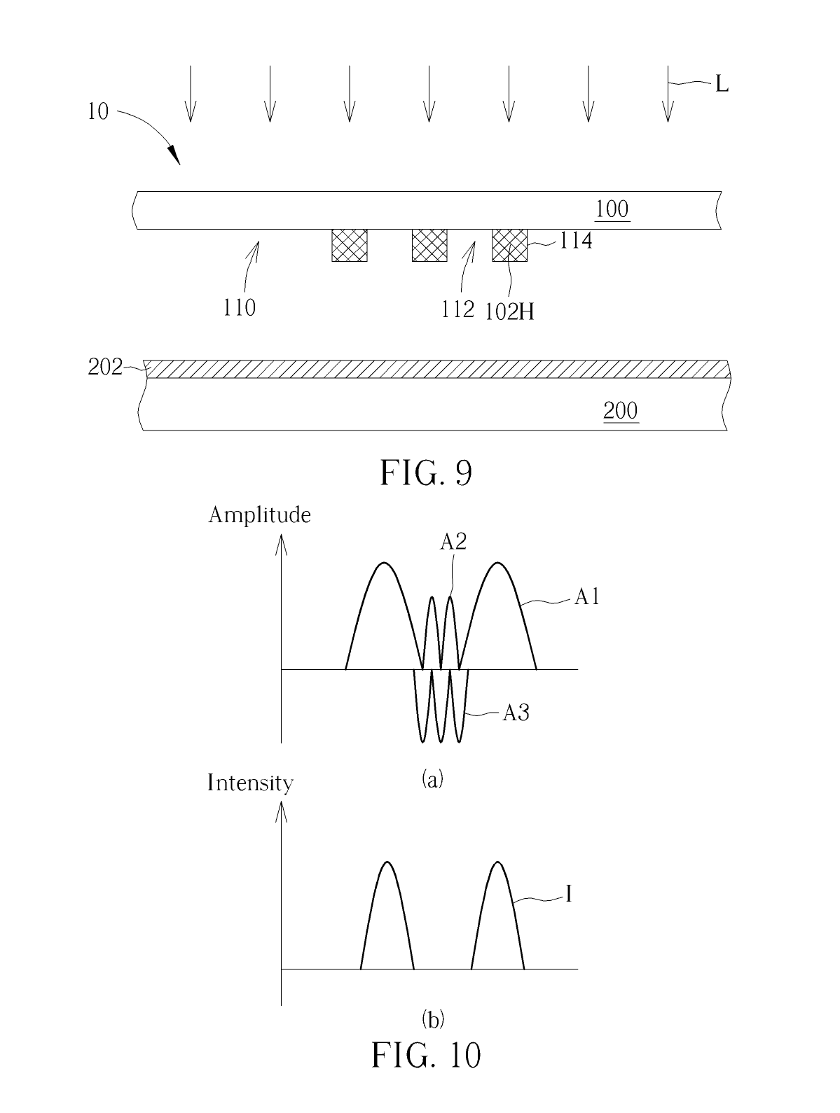

Referring FIG. 9 and FIG. 10, FIG. 9 is a schematic diagram illustrating applying the phase shift mask to a photolithography process of the embodiment of this invention, wherein the figure of the phase shift mask 10 illustrates a cross-sectional view taken along the cross-line A-A′ in FIG. 6, and FIG. 10 is a schematic diagram illustrating an exposure result of the phase shift mask of the embodiment of this invention. As described above, the phase shift mask 10 of this embodiment can be applied to the exposure process, so as to transfer the layout 150 in FIG. 1 to a target substrate 200. The target substrate 200 of this embodiment is a silicon wafer for example, but not limited thereto. Specifically, a photoresist layer 202 can be disposed on a surface of the target substrate 200. The pattern of the layout 150 on the phase shift mask 10 can be transferred to the photoresist layer 202 through exposure process, development process, and baking process first, and the pattern of the layout 150 can be transferred to the target substrate 200 by etching process next. The phase shift mask 10 of this embodiment includes the substrate 100 and the patterned phase shift layer 114. The patterned phase shift layer 114 is disposed on the substrate 100 and includes at least one device pattern aperture 110 and a plurality of dummy pattern apertures 112, wherein the device pattern aperture 110 and the dummy pattern apertures 112 expose a portion of the surface of the substrate 100, and the size of each dummy pattern aperture 112 is less than or equal to the resolution limit of the lithographic apparatus. It is noteworthy that the material of the patterned phase shift layer 114 includes high crosslinking degree material 102H having 100% light transmittance, and such material includes HOSP, MSQ, or HSQ for example, but not limited thereto. As shown in FIG. 9, in the phase shift mask 10 of this embodiment, the high crosslinking degree material 102H and the dummy pattern apertures 112 are disposed alternately between two adjacent device pattern apertures 110. In one example, the thickness of HOSP layer of this embodiment is about 183.3 nanometers and the refractive index of HOSP layer is about 1.525 when the wavelength of exposure light beam L used in the photolithography process is 193 nanometers. The exposure light beam L is illuminated downward from a side of the substrate 100 opposite to the patterned phase shift layer 114 and penetrate the phase shift mask 10 during the photolithography process (such as exposure process). Additionally, a phase difference between an exposure light beam L passing through the high crosslinking degree material 102H of the patterned phase shift layer 114 (may be regarded as the high crosslinking degree material 102H of the background region 104B) and an exposure light beam L passing through the device pattern apertures 110 or the dummy pattern apertures 112 can be 180 degrees. For example, when the phase angle of the exposure light beam L passing through the high crosslinking degree material 102H is 0 degree, the phase angle of the exposure light beam L passing through the device pattern apertures 110 or the dummy pattern apertures 112 is 180 degrees, and vice versa. Since the phase angle relates to the refractive index of the phase shift layer, the thickness of the phase shift layer, and the wavelength of the exposure light beam in the photolithography process, the thickness of the phase shift layer 114 (i.e., the abovementioned predetermined thickness D) is required to satisfy the following relation: P2π*(n−1)*d/λ, wherein P is the phase angle, n is the refractive index of the phase shift layer 114, d is the thickness of the phase shift layer 114, and λ is the wavelength of the exposure light beam in the photolithography process.

In FIG. 10, diagram (a) illustrates the amplitude distribution of the exposure light beam L on the target substrate 200 after passing through the phase shift mask 10 shown in FIG. 9, and diagram (b) illustrates the intensity distribution of the exposure light beam L on the target substrate 200 after passing through the phase shift mask 10 shown in FIG. 9. As shown in diagram (a), the amplitude distribution A1 corresponds to the exposure light beam L passing through the device pattern apertures 110, the amplitude distribution A2 corresponds to the exposure light beam L passing through the dummy pattern apertures 112, and the amplitude distribution A3 corresponds to the exposure light beam L passing through the high crosslinking degree material 102H. According to the description above, the phase difference between the exposure light beam L passing through the high crosslinking degree material 102H and the exposure light beam L passing through the device pattern apertures 110 or the dummy pattern apertures 112 is 180 degrees. Additionally, the intensities corresponding to the amplitude distribution A1 and the amplitude distribution A2 are presented by positive values, and the intensities corresponding to the amplitude distribution A3 are presented by negative values in diagram (a). Therefore, destructive interference occurs between the exposure light beam L passing through the high crosslinking degree material 102H and the exposure light beam L passing through the device pattern apertures 110 or the dummy pattern apertures 112. The result is shown in diagram (b), the intensity of the exposure light beam L passing through the high crosslinking degree material 102H and the intensity of the exposure light beam L passing through the dummy pattern apertures 112 on the target substrate 200 are approximately zero, and substantially only the intensity distribution I of the exposure light beam L corresponding to the device pattern apertures 110 can be observed on the target substrate 200. Accordingly, the photoresist layer 202 is illuminated by substantially mere the exposure light beam L that passes through the device pattern apertures 110. It is noteworthy that the waveform of the intensity distribution I of the exposure light beam L that passes through the device pattern apertures 110 are sharper than the waveform of the amplitude distribution A1 of the exposure light beam L that passes through the device pattern apertures 110. For example, the width of each wave of the intensity distribution I is less than the width of each wave of the amplitude distribution A1, the wave shape of the intensity distribution I is steeper than that of the amplitude distribution A1, and therefore the resolution of the exposure process can be enhanced. In another aspect, the side lobe effect can be effectively reduced by the destructive interference between the amplitude distribution A1, the amplitude distribution A2, and the amplitude distribution A3, so as to improve the yield or the quality of the photolithography process.

The phase shift mask 10 of this embodiment can be applied to form the layout including the device pattern of isolation region, semi-dense region, or dense region. Comparing the simulation results of the conventional phase shift mask and the phase shift mask 10 of this embodiment, when the phase shift mask 10 of this embodiment is used for respectively forming the device patterns of isolation region, semi-dense region, and dense region, the normalized image log-slopes (NILS) are enhanced by 9.09%, 7.33%, and 14.29% respectively, and the depth of focuses (DOF) under 5% exposure latitude (EL) are enhanced by 33.33%, 15.38%, and 133.33% respectively. In addition, the side lobe effect does not occur when the phase shift mask 10 is used for forming the device patterns of isolation region, semi-dense region, or dense region. However, under the same condition, the side lobe effect occurs when the conventional phase shift mask formed of MoSi material with 6% light transmittance is used for forming the device patterns of isolation region or semi-dense region. Therefore, the phase shift mask 10 of this embodiment can improve the condition window of the exposure process comparing to the conventional phase shift mask.

In addition, although the phase shift mask 10 of this embodiment is used for forming patterns of contact holes as an example, the phase shift mask 10 can also be used for forming other types of patterns in the layout, such as logic cells of the logic circuit, but not limited thereto. The phase shift mask 10 of this embodiment can not only be used for forming semiconductor devices on the semiconductor wafer, but can also be used for forming other types of devices on the glass substrate, the polymer substrate, or the quartz substrate. In addition, although the device pattern apertures 110 and the dummy pattern apertures 112 of this embodiment are disposed according to the arrangement shown in FIG. 6 for illustration, any design of uniformly, repeatedly, or alternately arrangement of the device pattern apertures 110 and the dummy pattern apertures 112 is included in the scope of this invention. Further, applications of the high crosslinking degree material 102H are also included in the scope of this invention.

To sum up, the fabrication method of the phase shift mask of this invention provides the phase shift layer having the predetermined thickness for forming the patterned phase shift layer in the phase shift mask. Further, according to this invention, the light transmittance of the material of the phase shift layer is 100%, and the dummy pattern apertures are disposed in the phase shift mask. Accordingly, the resolution of exposure process can be enhanced and the side lobe effect can be reduced due to the characteristic of 100% light transmittance of the phase shift mask and the destructive interferences of exposure light beam passing through the phase shift mask, and the total resolution of photolithography process can therefore be enhanced effectively. In addition, in the fabrication method of the phase shift mask of this invention, the material of the phase shift layer is crosslinking material, and the structure of the crosslinking material can be modified by illumination of the energy beam. Therefore, etching process is not required in the method of fabricating the phase shift mask of this invention, so that the surface of the substrate or the phase shift layer can be prevented from being damaged by etching process, and the uniformity of feature sizes of patterns formed on the phase shift mask can be improved. In another aspect, the method of fabricating the phase shift mask of this invention does not need to form any chrome film on the phase shift mask. Therefore, the fabrication method of the phase shift mask of this invention is simpler and can save more time or cost comparing to that of the conventional phase shift mask.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A phase shift mask configured to transfer a layout through a photolithography process, comprising:
a substrate; and
a patterned phase shift layer disposed on the substrate, wherein the patterned phase shift layer includes at least one device pattern aperture and a plurality of dummy pattern apertures, the at least one device pattern aperture and the dummy pattern apertures expose a portion of a surface of the substrate, and the dummy pattern apertures are disposed adjacent to the at least one device pattern aperture and surround the at least one device pattern aperture, wherein the patterned phase shift layer includes a predetermined thickness which makes a phase difference between an exposure light beam passing through the patterned phase shift layer and an exposure light beam passing through the at least one device pattern aperture or the dummy pattern apertures in the photolithography process be 180 degrees, and a light transmittance of the patterned phase shift layer is 100%;
wherein the at least one device pattern aperture corresponds to at least one device pattern of the layout, and the at least one device pattern is transferred to a target substrate through the photolithography process.

2. The phase shift mask according to claim 1, wherein distances between the at least one device pattern aperture and the dummy pattern apertures are greater than 0 micrometer.

3. The phase shift mask according to claim 1, wherein a distance between any two adjacent dummy pattern apertures is less than or equal to a size of the dummy pattern apertures.

4. The phase shift mask according to claim 3, wherein the size of the dummy pattern apertures is less than or equal to a resolution limit of a lithographic apparatus.

5. The phase shift mask according to claim 1, wherein the dummy pattern apertures are disposed in a matrix arrangement in the patterned phase shift layer.

6. The phase shift mask according to claim 1, wherein the predetermined thickness of the patterned phase shift layer satisfies following relation: P=2π*(n−1)*d/λ, wherein P is a phase angle, n is a refractive index of the patterned phase shift layer, d is the predetermined thickness, and λ is a wavelength of the exposure light beam in the photolithography process.

7. The phase shift mask according to claim 1, wherein patterns of the dummy pattern apertures are not transferred to the target substrate in the photolithography process.

8. A fabrication method of a phase shift mask, wherein the phase shift mask is applied to transfer a layout through a photolithography process, and the layout comprises at least one device pattern, the fabrication method of the phase shift mask comprising:
forming a phase shift layer with a predetermined thickness on a substrate, and defining at least one predetermined device region, a plurality of dummy pattern regions, and a background region on the substrate, wherein the at least one predetermined device region corresponds to the at least one device pattern of the layout;
performing a partial irradiation process to the phase shift layer by using an energy beam to illuminate the phase shift layer, wherein the energy beam illuminates the background region but does not illuminate the at least one predetermined device region and the dummy pattern regions; and
patterning the phase shift layer, wherein a portion of the phase shift layer in the at least one predetermined device region and the dummy pattern regions is removed, a portion of the phase shift layer in the background region is retained, so as to form at least one device pattern aperture and a plurality of dummy pattern apertures in the phase shift layer, wherein the at least one device pattern aperture and the dummy pattern apertures expose a portion of a surface of the substrate.

9. The fabrication method of the phase shift mask according to claim 8, wherein the partial irradiation process comprises an electron beam irradiation process.

10. The fabrication method of the phase shift mask according to claim 8, wherein the dummy pattern apertures are disposed adjacent to the at least one device pattern aperture and surround the at least one device pattern aperture, and distances between the at least one device pattern aperture and the dummy pattern apertures are greater than 0 micrometer.

11. The fabrication method of the phase shift mask according to claim 8, wherein a distance between any two adjacent dummy pattern apertures is less than or equal to a size of the dummy pattern apertures.

12. The fabrication method of the phase shift mask according to claim 11, the size of the dummy pattern apertures is less than or equal to a resolution limit of a lithographic apparatus.

13. The fabrication method of the phase shift mask according to claim 8, wherein the dummy pattern apertures are disposed in a matrix arrangement.

14. The fabrication method of the phase shift mask according to claim 8, wherein a light transmittance of the phase shift layer is 100%.

15. The fabrication method of the phase shift mask according to claim 8, wherein a phase difference between an exposure light beam passing through the background region of the phase shift layer and an exposure light beam passing through the at least one device pattern aperture or the dummy pattern apertures in the photolithography process is 180 degrees.

16. The fabrication method of the phase shift mask according to claim 15, wherein the predetermined thickness of the phase shift layer satisfies following relation: P=2π*(n−1)*d/λ, wherein P is a phase angle, n is a refractive index of the phase shift layer, d is the predetermined thickness, and λ is a wavelength of the exposure light beam in the photolithography process.

17. The fabrication method of the phase shift mask according to claim 8, wherein the step of patterning the phase shift layer comprises performing a developing process, and a solvent used in the developing process comprises propyl acetate.
